(19) United States
(12) Patent Application Publication
(10) Pub. No.: US 2018/0128862 A1
(43) Pub. Date: May 10, 2018

(54) Autonomous Monitoring System for Power Distribution System, Distribution System Monitoring Method, and First Device Used in Autonomous Monitoring System for Power Distribution System

(71) Applicant: Hitachi, Ltd., Chiyoda-ku, Tokyo (JP)

(72) Inventors: Hiroki SATOH, Tokyo (JP); Kazuya SHOJIKI, Tokyo (JP); Masahiro ADACHI, Tokyo (JP)

(21) Appl. No.: 15/574,211

(22) PCT Filed: Mar. 22, 2016
(86) PCT No.: PCT/JP2016/058982

§ 371 Date: Nov. 15, 2017

(30) Foreign Application Priority Data
Jun. 11, 2015 (JP) 2015-118237

(51) Int. Cl. G01R 19/25; G06Q 50/06; H02J 13/00

(52) U.S. Cl. CPC G01R 19/2513; G05B 19/02; H02J 13/0013; G06Q 50/06

(57) ABSTRACT

Provided is an autonomous monitoring system capable of measuring and monitoring the state of a power distribution system. The monitoring system that autonomously monitors the state of a power distribution system is provided with a first device made correspond to a predetermined control device installed in the power distribution system; a second device for measuring the state of the power distribution system on the upstream side of the predetermined control device; and a third device for measuring the state of the power distribution system on the downstream side of the predetermined control device. The first device, second device, and third device are connected so as to be bi-directionally communicable with each other over a first communication channel. The first device collects the measurement results of the second device and third device to monitor the power distribution system. The first device can stabilize the power distribution system by controlling the predetermined control device.

### TECHNICAL FIELD

The present invention relates to an autonomous monitoring system for a power distribution system, a distribution system monitoring method, and a first device used in an autonomous monitoring system for a power distribution system.

### BACKGROUND ART

High-voltage power generated at large power plants such as hydroelectric power plants, thermal power plants, and nuclear power plants is sent to substations in various places through a power transmission network. The substations adjust the voltage or the like, and supplies power to each customer through a power distribution network. In order to supply high quality power to customers, it is necessary to operate electric facilities such as power plants, substations and electric lines reasonably and economically. This operation task is called a power supply operation.

In the power supply operation in the related art, it is assumed that power is distributed in one direction from power plants to customers. However, in recent years, a distributed power supply utilizing renewable energy such as sunlight and wind power is spreading from the viewpoint of environmental protection and the like. The power supply operation so far is a one-way power distribution from power plants to customers. In the future, however, with the spread of the distributed power supply, a bidirectional power distribution era will come in which power is supplied from a customer having the distributed power supply to a power distribution network.

Therefore, in a bidirectional power distribution system including a large number of distributed power supplies, it is necessary to apply system redundancy and system operation, which had been implemented in the power transmission network, also to the power distribution network. However, in a case of a large-scale centralized power supply such as a thermal power plant, its output is stable, but in a case of the distributed power supply that uses renewable energy, such as photovoltaic power generator and wind power generator, the output changes suddenly depending on the amount of solar radiation, the wind speed, or the like. If many unstable distributed power supplies which change depending on the change of the natural environment are connected to the power distribution network in this way, it becomes difficult to control the voltage and frequency of the power distribution network within a certain range, so power quality and the reliability of the power distribution may be lowered.

In order to eliminate the influence from the distributed power supply connected to the power distribution network, adding a number of new monitoring devices that measure voltage or the like in the power distribution network, or introducing a new control device corresponding to bidirectional power distribution increases the cost significantly.

Further, it is difficult for the power transmission and distribution business operator to know beforehand when and where the distributed power supply of how much output is provided or when the existing distributed power supply is to be removed. Therefore, it is difficult for the power transmission and distribution business operator to predict the amount of power flowing into the power distribution network from the distributed power supply or to know the state of the voltage of the power distribution network or the like. Since the distributed power supply is added to, relocated in, or removed from the power distribution network at a timing when it is difficult to predict it, it is difficult to properly perform the power supply operation depending on the changing situation of the power distribution network.

In response to such a problem, PTL 1 attempts to realize a stable output by combining a wind power generator and a storage battery. In PTL 1, in a case where the power generation amount of the wind power generator is large, excess power is stored in the storage battery; and in a case where the power generation amount of the wind power generator is small, power is discharged from the storage battery. By combining the storage battery and the distributed power supply, the output can be stabilized.

In PTL 2, an independent component analysis method is used to separate the output of the distributed power supply included in the existing signal source of a certain power flow as an independent component. In this way, in PTL 2, the distributed power supply connected to the power distribution network can be detected and its output can be estimated.

### CITATION LIST

### Patent Literature

PTL 1: Japanese Patent No. 4896233
PTL 2: JP-A-2012-95478

### SUMMARY OF INVENTION

### Technical Problem

In PTL 1, although a storage battery is used in combination with a distributed power supply, the introduction cost of the storage battery is still high at present. On the other hand, it is not realistic to introduce large capacity of expensive storage batteries into the power distribution network because it requires a large capacity storage battery in order to sufficiently cope with the output change of the distributed power supply. Further, since a power transmission and distribution business operator cannot know the introduction timing and capacity of the storage battery, it is difficult to control power transmission considering the introduction of the storage battery.

In PTL 2, although the output of the distributed power supply can be estimated, in a case where the estimation accuracy decreases, the influence of the reverse flow cannot be eliminated, and the power quality may decrease. In the actual power distribution system, deterioration of other power transmission and distribution cables, power operation apparatuses, or the like in addition to the distributed power supply is also included in observation points. Therefore, it is difficult to estimate the output of the distributed power supply with only one observation point, and it is necessary to add observation points to improve estimation accuracy.

An object of the present invention is to provide an autonomous monitoring system for a power distribution system capable of measuring and monitoring the state of a power distribution system, a distribution system monitoring method, and a first device used in autonomous monitoring system for a power distribution system. Another object of the present invention is to provide an autonomous monitoring system for a power distribution system, a distribution system monitoring method, and a first device used in an autonomous monitoring system for a power distribution system, in which the state of the power distribution system is estimated, and it possible to deal with an event on the spot according to the estimated state.

### Solution to Problem

In order to solve the above problems, a monitoring system that autonomously monitors the state of a power distribution system according to the present invention includes a first device corresponding to a predetermined control device installed in the power distribution system, a second device for measuring the state of the power distribution system on the upstream side of the predetermined control device, and a third device for measuring the state of the power distribution system on the downstream side of the predetermined control device, in which the first device, the second device, and the third device are connected so as to be bi-directionally communicable with each other over a first communication channel, and the first device collects a measurement result of the second device and a measurement result of the third device to monitor the power distribution system.

### Advantageous Effects of Invention

According to the present invention, the first device corresponding to the predetermined control device provided in the power distribution system collects measurement results of the second device and the third device which are located on the upstream side and the downstream side to be able to monitor the power distribution system. Therefore, according to the present invention, the first device can immediately monitor the power distribution system at that location.

### BRIEF DESCRIPTION OF DRAWINGS

FIG. 1 is a system configuration diagram showing an entire power distribution system provided with an autonomous monitoring system.

FIG. 2 is a block diagram of a control node and a sensor node.

FIG. 3 is a block diagram of an aggregation node and a cloud node.

FIG. 4 is an example of a database in which observed values are recorded.

FIG. 5 is an example of a database in which statistical values are recorded as a graph.

FIG. 6 is an example of a communication channel table.

FIG. 7 is an example of a database in which relationships between nodes are recorded.

FIG. 8 is a flowchart showing the process of checking an operation mode.

FIG. 9 is a sequence diagram showing processes in which adjacent control nodes share observation value statistical information.

FIG. 10 is an explanatory diagram showing how adjacent control nodes cooperate to change the configuration of the power distribution system, (a) shows a state before switching the power distribution system, and (b) shows a state after switching the power distribution system.

FIG. 11 is a sequence diagram showing a system switching process in a case where reverse flow is detected.

FIG. 12 is a statistical value graph showing an example of criteria for determining whether to switch the route.

FIG. 13 is a diagram showing an entire power distribution system provided with an autonomous monitoring system according to a second embodiment, and showing a state in which a part of the power distribution path is disconnected.

FIG. 14 is a diagram showing an entire power distribution system in a case where system switching is performed from disconnection.

FIG. 15 is a sequence diagram showing a system switching process in a case where disconnection is detected.

FIG. 16 is an explanatory diagram showing a hierarchical aggregation node and a management table that defines a range for exchanging information between control nodes, according to a third embodiment.

### DESCRIPTION OF EMBODIMENTS

Hereinafter, embodiments of the present invention will be described with reference to the drawings. As will be described below, in the present embodiment, an autonomous distributed control node 1 and sensor nodes 2 and 3 are added to each predetermined point of the power distribution system in which a distributed power supply 9 of renewable energy is provided, and thus the power distribution system is efficiently monitored. Furthermore, in the present embodiment, the state of the power distribution system is estimated based on the measurement result of each predetermined point, and the configuration of the power distribution system is changed according to the estimation result.

The control node 1 and the sensor nodes 2 and 3 of the present embodiment can mutually recognize and communicate with each other through, for example, the first communication channel CN1 using short-range wireless communication. For example, the control node 1 and the sensor nodes 2 and 3 recognize whether there is another node within a communication range where communication is possible through a first communication channel CN1 and communicates with the recognized different node by a packet relay method.

The power transmission and distribution business operator can install the control node 1 and the sensor nodes 2 and 3 at predetermined points in the power distribution system. A plurality of predetermined points can be set in the power distribution system, and each set of the control node 1 and the sensor nodes 2 and 3 can be provided at each of the predetermined points. However, it is not necessary that the configurations of all sets are the same, one set may be configured with the control node 1 and the sensor node 2, another set may be configured with the control node 1 and the sensor node 3, still another set may be configured with at least one of the sensor nodes 2 and 3, and further still another set may be configured with only the control node 1.

The control node 1 is provided corresponding to the opening/closing device 7 which is an example of “predetermined control device” provided in the power distribution system, for example. Besides the opening/closing device 7, the “predetermined control device” includes, for example, an automatic voltage regulator and a reactive power compensator. The control node 1 may be formed separately from the predetermined control device or may be provided inside the predetermined control device.

The sensor nodes 2 and 3 are preferably provided on the upstream side and the downstream side of the opening/closing device 7. Therefore, the sensor node 2 located on the upstream side of the control node 1 can also be called an upstream side sensor node 2 (or an upstream side sensor 2). The sensor node 3 located on the downstream side of the control node 1 can also be called a downstream side sensor node 3 (or a downstream side sensor 3).

Here, the upstream side and the downstream side are defined based on the direction of a current in the power distribution system. Since the side on which a substation 6 on the power distribution system is provided has a high voltage, it is the upstream side. On the other hand, since the side on which a load LD is provided has a low voltage, it is the downstream side.

However, in a case where the output voltage of the distributed power supply 9 becomes higher than the voltage of the power distribution system, a current may flow in the opposite direction. For example, in a case of photovoltaic power generators, the generated voltage changes according to the change in the amount of solar radiation. In the case of a wind power generator, the generated voltage changes due to changes in wind speed and wind direction. Due to the change in these output voltages, a phenomenon in which a current flows from the distributed power supply 9 to the power distribution system in the opposite direction to the usual is called a reverse flow.

In the present embodiment, among sets of the control node 1 and the sensor nodes 2 and 3 disposed at respective points, the control nodes 1 within a predetermined range exchange information with each other. The control node 1 at each point accumulates the information autonomously measured by the sensor nodes 2 and 3 at each point as it is or after processing. Then, the control nodes 1 within a predetermined range exchange information (monitoring information) accumulated by them at a predetermined timing through the first communication channel CN1.

The control nodes 1 can exchange information with each other within a meaningful range of information exchange. The information exchange means that, for example, the control node 1 can use the information received from another control node 1 to control the control device (such as the opening/closing device 7) that is the connection destination of the self node 1. In other words, the control node 1 estimates the state of the power distribution system by exchanging information with a different control node 1, and controls the control device (such as the opening/closing device 7) so that the power distribution system becomes stable. The control node 1 at each point estimates the existence of the distributed power supply 9 connected to the power distribution system and the output fluctuation thereof, and uses the estimation result to stabilize the power distribution system at the point.

The autonomous monitoring system of the present embodiment adds a partial autonomous control function to the existing central management type system control system. In the present embodiment, it is possible to add an autonomous monitoring function and an autonomous control function to places where the existing central management type system control system cannot perform sufficient monitoring. Thus, in the present embodiment, it is possible to promptly detect events such as output fluctuation (reverse flow) of the distributed power supply 9 and disconnection of the power distribution line, and immediately perform control to deal with the event on the spot.

For example, when reverse flow occurs, power loss is minimized by controlling the opening/closing device 7 to change the system. Thus, in the present embodiment, economical system operation is realized. Further, for example, at the time of a ground fault or a short circuit fault, the surrounding control nodes 1 instantaneously exchange information, identify a system in which the problem occurs, and separate the problematic system from the power distribution system. As described above, in the present embodiment, by appropriately changing the channel, the power supply is restored promptly.

In the present embodiment, the control node 1 is associated with a control device such as the opening/closing device 7, and thus the function of the control device can be expanded by so-called retrofitting. In the present embodiment, since existing facilities can be effectively utilized, development cost and installation cost can be reduced, and the system control system can be improved at a relatively low cost.

In the present embodiment, the control node 1 and the sensor nodes 2 and 3 at respective points communicate with each other through the first communication channel CN1 using short-range wireless communication, mutually recognize, and establish a communication channel. Therefore, it is unnecessary to connect respective nodes with a communication cable, and a communication channel between nodes can be constructed relatively easily and at low cost.

In the present embodiment, by merely installing the control node 1 and the sensor nodes 2 and 3 in the necessary place on the power distribution system, the nodes 1, 2, 3 autonomously construct the communication channel CN1, and performs control to stabilize the power distribution system as required. Therefore, even in a case where the control device (such as the opening/closing device 7) and the distributed power supply 9 are added to, removed from, or relocated in the power distribution system, or the power distribution path of the power distribution system branches off, it is possible to cope with these configuration changes, only by installing or relocating the nodes 1, 2, and 3 according to the configuration changes. Thus, in the present embodiment, it is not necessary to redo the communication settings of the respective nodes 1, 2, 3, and the operation cost can be reduced.

### Embodiment 1

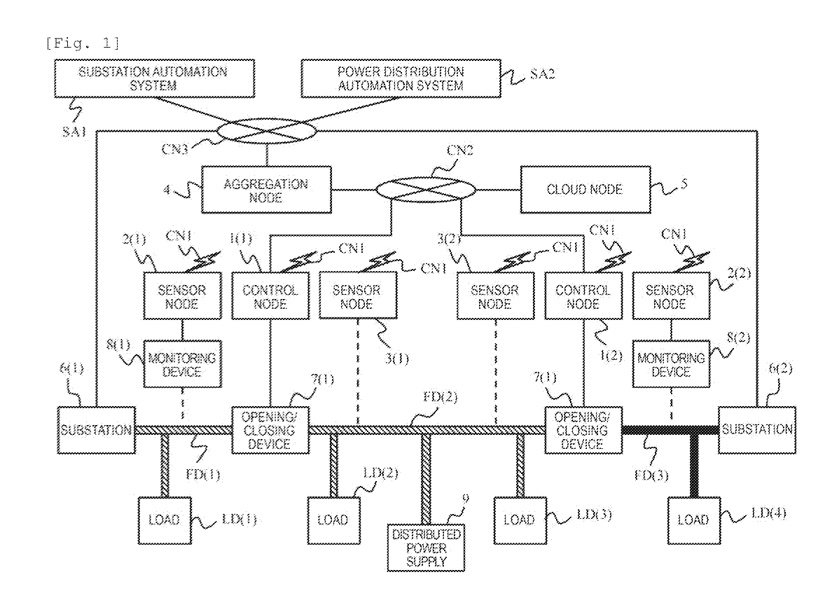

A first embodiment will be described with reference to FIG. 1 to FIG. 12. FIG. 1 shows the entire configuration of a power distribution system with an autonomous monitoring system according to the present embodiment.

As will be described later, the power distribution system of the present embodiment includes elements 6, 7, 8, 9, LD, and FD constituting the power distribution system, elements SA1 and SA2 controlling the power distribution system, elements 1, 2, and 3 monitoring the power distribution system, an element 4 making a control determination as a whole power distribution system based on the monitoring result of the power distribution system (the result estimated from the measurement result), and an element 5 supporting the elements 1, 2, and 3 monitoring the power distribution system.

The power distribution system, which is a part of the power system, includes, for example, substations 6(1) and 6(2), opening/closing devices 7(1) and 7(2), monitoring devices 8(1) and 8(2), a distributed power supply 9, loads LD(1) to LD(4), and power distribution lines FD(1) to FD(3).

Hereinafter, in a case of not being particularly distinguished, numbers with parentheses such as (1) and (2) attached to reference numerals are omitted. For example, the substations 6(1) and 6(2) are abbreviated as a substation 6, the control nodes 1(1) and 1(2) are abbreviated as a control node 1, the sensor nodes 2(1) and 2(2) are abbreviated as a sensor node 2, and the power distribution lines FD(1) to FD(3) are abbreviated as a power distribution line FD.

The substation 6 adjusts the voltage of power sent from a large-scale centralized power supply (such as a thermal power plant and a nuclear power plant) (not shown), and sends it to the power distribution line FD. Power sent from substation 6 is supplied to each load LD. Examples of the load LD include electrical products in the home, electrical equipment in the factory, or the like.

The opening/closing device 7 is provided in the middle of the power distribution line FD, and blocks or connects the power distribution line FD in the middle. By opening or closing the opening/closing device 7, the power distribution line FD in which a problem occurs is separated from the power distribution system, or the power distribution line FD restored from the failure is reconnected to the power distribution system. The monitoring device 8 is provided in the middle of the power distribution line FD, and monitors, for example, active power, reactive power, voltage, or the like. The distributed power supply 9 is, for example, a photovoltaic power generator, a wind power generator, or the like.

The substation automation system SA1 and the power distribution automation system SA2 are connected to the substation 6 through the third communication channel CN3. These automation systems SA1 and SA2 are responsible for controlling the entire power distribution system. In the following description, these automation systems SA1 and SA2 are sometimes called external other systems SA1 and SA2.

The control node 1 and sensor nodes 2 and 3 are provided at predetermined positions (predetermined points) of the power distribution system, and autonomously construct a monitoring system to monitor the power distribution system. The control node 1 corresponds to “a first device”, the sensor node 2 corresponds to “a second device”, and the sensor node 3 corresponds to “a third device”.

The control node 1 and the sensor nodes 2 and 3 are connected through the first communication channel CN1 so as to be bi-directionally communicable with each other. The first communication channel CN1 is configured, for example, like a short-range wireless communication network. Each node automatically detects adjacent nodes, and autonomously constructs a communication network.

The sensor node 2 is provided on the upstream side of the opening/closing device 7. The sensor node 2 corresponds to the monitoring device 8. The monitoring device 8 monitors the state of the opening/closing device 7. For example, the monitoring device 8 monitors the voltage value or the like of the power distribution line provided with the opening/closing device 7. If the value detected by the monitoring device 8 reaches the threshold value, the opening/closing device 7 operates to block or reconnect the power distribution line.

As described above, the opening/closing device 7 and the monitoring device 8 are related to each other, and both may be configured to be integrated. Since the sensor node 2 is connected to the monitoring device 8, the sensor node 2, the monitoring device 8, and the opening/closing device 7 may be configured to be provided in the same housing. It may be configured such that the sensor node 2, the monitoring device 8, and the opening/closing device 7 are separately formed and connected to each other. In this manner, the sensor node 2 on the upstream side is configured to use the existing monitoring device 8. In other words, by adding a computer program or the like to the existing monitoring device 8, the sensor node 2 can be built in the monitoring device 8.

The sensor node 3 is provided on the downstream side of the opening/closing device 7. The sensor node 3 does not correspond to the monitoring device 8. In a case of one-way power distribution from a centralized power supply to customers through a substation, only the system state on the upstream side (substation side) may be known, and the system state on the downstream side (load side) is not particularly necessary. Therefore, the monitoring device 8 is not provided on the downstream side of the opening/closing device 7 in the existing power distribution system. Therefore, in the present embodiment, in order to measure the state of the downstream side of the opening/closing device 7, that is, the system state (such as active power, reactive power, and voltage) of the load side, the sensor node 3 incorporating the observation device 305 is provided.

The sensor node 3 entrusts an accumulation and statistical process of the observation data (also referred to as observation values) and a system state estimation process to the cloud node 5 which is an external device. Since the accumulation function or the like and the system state estimation function F53 to be described later are removed from the sensor node 3 and provided in the cloud node 5, the configuration of the sensor node 3 can be simplified and the manufacturing cost can be reduced. From the measurement result of the sensor node 3, the control node 1 can detect the presence and output fluctuation of the distributed power supply 9 provided on the load side.

The control node 1 monitors the state of the power distribution system from the measurement results of the sensor node 2 and sensor node 3. Examples of the state of the power distribution system to be monitored include presence of the distributed power supply 9, the output fluctuation of the distributed power supply 9, disconnection of the power distribution line FD, or the like. The control node 1 controls the operation of the opening/closing device 7 based on the monitoring result, that is, based on the measurement results of the sensor nodes 2 and 3. When the opening/closing device 7 opens, the power distribution line FD provided with the opening/closing device 7 is blocked. When the opening/closing device 7 is closed, the blocked power distribution line FD is reconnected.

The control node 1 can be provided in the opening/closing device 7 or outside the opening/closing device 7. In addition, the control node 1 can also be provided in the control device of the distributed power supply 9.

The aggregation node 4 is connected bi-directionally communicably with each control node 1 and cloud node 5 through the second communication channel CN2. Furthermore, the aggregation node 4 is connected through the third communication channel CN3 to the substation automation system SA1 and the power distribution automation system SA2 so as to be bidirectionally communicable with each other. For example, the second communication channel CN2 can be configured as a wireless communication network of a relatively long distance such as a mobile phone communication network. For example the third communication channel CN3 can be configured as a wired communication network using optical fiber lines and metal lines.

The aggregation node 4 knows the state of the power distribution system under its control, based on the information from the control node 1, the sensor nodes 2 and 3, and the cloud node 5, and cooperates with other systems such as the substation automation system SA1 and the power distribution automation system SA2.

In response to a request from the sensor node 3, the cloud node 5 accumulates data (data of the observation value) measured by the sensor node 3, and statistically processes the accumulated data. The cloud node 5 is capable of communicating with the sensor node 3 through the control node 1.

The cloud node 5 communicates with the control node 1 through the second communication channel CN2, and communicates with the sensor node 3 from the control node 1 through the first communication channel CN1. The sensor node 3 communicates with the control node 1 through the first communication channel CN1, and communicates with the cloud node 5 from the control node 1 through the second communication channel CN2. Similarly, the aggregation node 4 can also communicate with the respective sensor nodes 2 and 3 through the second communication channel CN2, the control node 1, and the first communication channel CN1.

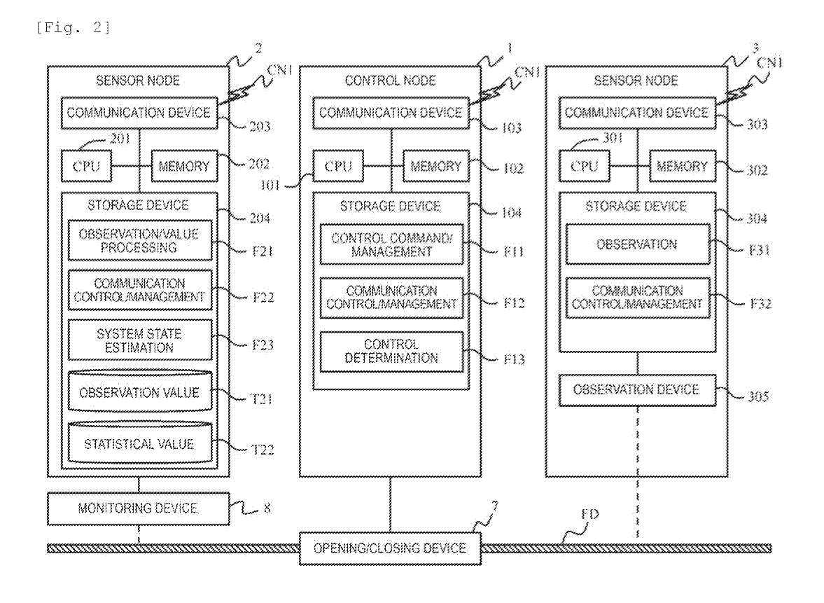

A configuration example of the control node 1 and the sensor nodes 2 and 3 will be described with reference to FIG. 2. The control node 1 includes, for example, a processor 101 as an “arithmetic processing unit”, a memory 102, a communication device 103 as a“communication unit”, and a storage device 104. The storage device 104 is an example of a “storage unit”. The storage device 104 and the memory 102 may cooperate to constitute a “storage unit”. The same applies to other storage devices 204, 304 and memories 202 and 302 which will be described later.

The storage device 104 is configured with, for example, a rewritable nonvolatile memory such as a flash memory device. It may be configured such that a volatile memory is backed up by a battery or the like and is used. Other storage devices 204 and 304 can be configured similarly.

In the storage device 104, a computer program for realizing the predetermined functions F11 to F13 is stored. The control command/management function F11 controls generation of a control command or the like for the opening/closing device 7. The communication control/management function F12 controls communication among the sensor nodes 2 and 3 and the aggregation node 4 and the cloud node 5. The control determination function F13 makes a determination about the opening/closing operation of the opening/closing device 7, based on the measurement results of the sensor nodes 2 and 3. In some cases, the following description may be made by attaching reference symbols of predetermined functions to computer programs for realizing the functions, such as the control command/management function F11, the communication control/management function F12, and the control determination function F13.

The processor 101 reads the computer programs F11 to F13 stored in the storage device 104 into the memory 102 as necessary and executes it. Thus, each of the functions F11 to F13 is realized.

Although a line connecting the opening/closing device 7 and the communication device 103 is omitted in FIG. 2, the processor 101 is capable of communicating with the opening/closing device 7 through the communication device 103, and issue a control command to the opening/closing device 7. Further, the processor 101 communicates with the sensor nodes 2 and 3 and another control node 1 through the communication device 103 and the first communication channel CN1. Further, the processor 101 communicates with the aggregation node 4 and the cloud node 5 through the communication device 103 and the second communication channel CN2.

The sensor node 2 is associated with the monitoring device 8 located on the upstream side of the opening/closing device 7, and includes, for example, a processor 201, a memory 202, a communication device 203, and a storage device 204.

The storage device 204 stores a computer program for realizing the predetermined functions F21 to F23 and databases T21 and T22. The processor 201 reads the computer programs F21 to F23 into the memory 202 as necessary and executes it. Thus, each of the functions F21 to F23 is realized.

The observation/value processing function F21 observes the state of the power distribution system through the monitoring device 8 and stores the observation value in the observation value database T21. Furthermore, the observation/value processing function F21 statistically processes the observation value, and stores the result in the statistical value database T22.

The communication control/management function F22 controls communication with the monitoring device 8, the control node 1, adjacent nodes, the aggregation node 4, and the cloud node 5. Although the line connecting the monitoring device 8 and the communication device 203 is omitted, the processor 201 is connected to the monitoring device 8 through the communication device 203. The data (observation value) measured by the monitoring device 8 is sent from the power distribution line FD or the like to the sensor node 2 through the communication device 203. The processor 201 is capable of communicating with the control node 1 and other adjacent nodes through the communication device 203 and the first communication channel CN1. Further, the processor 201 is capable of communicating with the aggregation node 4 and the cloud node 5 through the control node 1.

Based on the observation value database T21 and the statistical value database T22, the system state estimation function F23 estimates how the power distribution system changes in the future and what type of distributed power supply 9 is connected.

Since the sensor node 2 of the present embodiment has the system state estimation function F23, basically, it is not necessary to entrust the system state estimation process to the cloud node 5. However, for example, in a case where the algorithm of the system state estimation function F53 of the cloud node 5 has better performance than the system state estimation function F23 of sensor node 2, observation values are transmitted from the sensor node 2 to the cloud node 5, and system state estimation may be requested.

The sensor node 3 is located on the downstream side of the opening/closing device 7, and is provided in the power distribution system. The sensor node 3 includes, for example, a processor 301, a memory 302, a communication device 303, a storage device 304, and an observation device 305.

By being connected to the power distribution line FD, the observation device 305 monitors the state of the power distribution system and acquires observation values. The observation values acquired by the observation device 305 is transmitted to the cloud node 5 through the sensor node 3.

The storage device 304 stores a computer program for realizing each of the functions F31 and F32. The processor 301 reads a computer program in the storage device 304 into the memory 302 as necessary, and executes it. Thus, each of the functions F31 and F32 is realized.

The observation function F31 observes the state (active power, reactive power, voltage, or the like) of the power distribution system using the observation device 305. The observation function F31 transmits the observation value to the cloud node 5, and makes a request for the estimation of the system state.

The communication control/management function F32 communicates with the control node 1 through the communication device 303 and the first communication channel CN1. Further, the communication control/management function F32 is capable of communicating with the cloud node 5 and the aggregation node 4 through the control node 1 and the second communication channel CN2.

The difference between the sensor node 2 that uses the existing monitoring device 8 and the sensor node 3 that is newly added to the power distribution system is in whether or not the sensor node itself owns the observation device, holds the function of processing the observation value, or owns a database. In order to own the functions of processing the observation values and the database, a high speed processor and a large capacity storage device are required. Therefore, the high speed processor and the large capacity storage device are installed in the sensor node 3, the manufacturing cost of the sensor node 3 increases.

Therefore, in the present embodiment, the sensor node 3 requests the cloud node 5 to process the data without storing the observation value and the statistical value in the storage device 304. Therefore, the sensor node 3 can reduce the capacity of the storage device 304 as compared with the sensor node 2 on the upstream side, so that the performance of the processor 301 needs not be high performance. Thus, in the present embodiment, the manufacturing cost of the sensor node 3 can be made smaller than the manufacturing cost of the sensor node 2. Therefore, in the present embodiment, since the sensor node 3, which can be manufactured at relatively low cost, can be disposed on the load side of the power distribution system, the state of the power distribution system can be relatively accurately estimated.

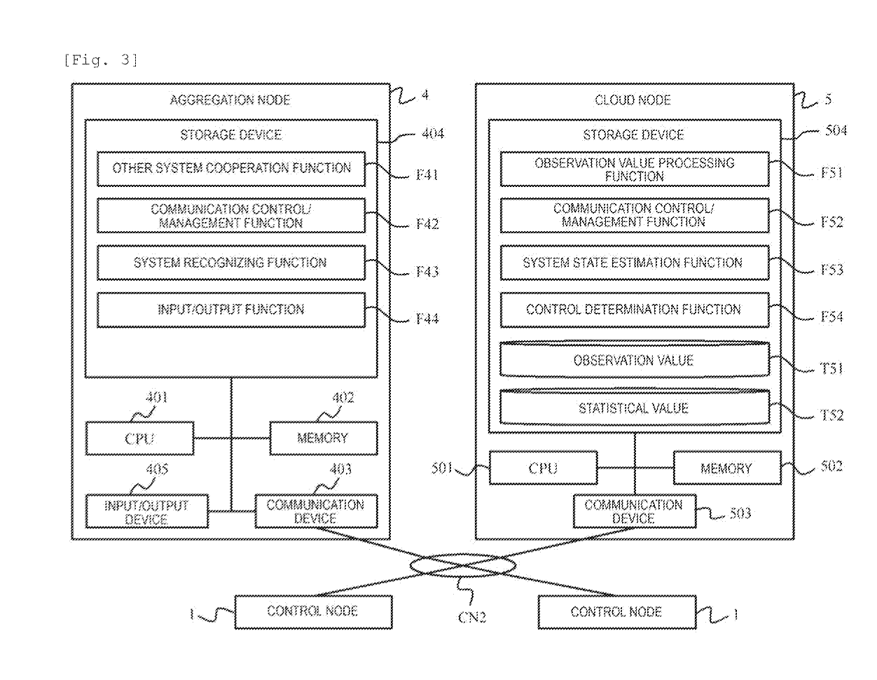

The configurations of the aggregation node 4 and the cloud node 5 will be described using FIG. 3. First, the configuration of the cloud node 5 will be described.

The cloud node 5 is a device that takes over a part of the processes relating to the sensor node 3 newly disposed on the downstream side (load side) of the power distribution system. Since one cloud node 5 takes over a part of the processes of the plurality of sensor nodes 3, the cost as the whole autonomous monitoring system can be reduced. However, it may be configured such that the cloud node 5 is abolished, and each sensor node 3 stores observation values and estimates the system state.

The cloud node 5 includes, for example, a processor 501, a memory 502, a communication device 503, and a storage device 504.

The storage device 504 is configured with, for example, a rewritable nonvolatile memory medium such as a flash memory device and a hard disk drive, and stores computer programs for realizing the predetermined functions F51 to F54 and databases T51 and T52.

The processor 501 reads the computer programs stored in the storage device 504 into the memory 502 as necessary and executes it. Thus, each of the functions F51 to F54 is realized.

The storage device 504 stores an observation value processing function F51, a communication control/management function F52, a system state estimation function F53, and a control determination function F54. The value (monitoring data) observed by the sensor node 3 is sent to the cloud node 5 through first communication channel CN1, the control node 1, and the second communication channel CN2. The observation value processing function F51 stores the observation values acquired from each sensor node 3 in the observation value database T51. The observation value processing function F51 statistically processes the observation values stored in the observation value database T51, and stores the statistically processed data in the statistical value database T52.

The communication control/management function F52 communicates with the control node 1 and the aggregation node 4 through the communication device 503 and the second communication network CN2. Further, the communication control/management function F52 communicates with the sensor node 3 through the control node 1 and the first communication channel CN1. The communication control/management function F52 can also communicate with the sensor node 2.

Based on the contents stored in the observation value database T51 and the statistical value database T52, the system state estimation function F53 estimates how the power distribution system changes in the future and what type of distributed power supply 9 is connected.

The control determination function F54 determines how to control the operation of the opening/closing device 7 which is the predetermined control device, based on the estimation result of the system state estimation function F53.

The configuration of the aggregation node 4 will be described. The aggregation node 4 knows the entire power distribution system under its management, and cooperates with other systems SA1 and SA2. The aggregation node 4 includes, for example, a processor 401, a memory 402, a communication device 403, a storage device 404, and an input/output device 405.

The storage device 404 can be configured with, for example, a rewritable nonvolatile memory medium such as a flash memory device or a hard disk drive. The storage device 404 stores a computer program for realizing each of the functions F41 to F44.

The processor 401 reads the computer programs stored in the storage device 404 into the memory 402 as necessary and executes it. Thus, each of the functions F41 to F44 is realized.

The communication device 403 communicates with the control node 1, the sensor nodes 2 and 3, and the cloud node 5 through the second communication channel CN2. The aggregation node 4 and the sensor nodes 2 and 3 communicate with each other through the control node 1 and the first communication channel CN1. Further, the communication device 403 is also connected to the substation automation system SA1 and the power distribution automation system SA2 through the third communication channel CN3.

In addition, it may be configured such that the first communication channel CN1 and the second communication channel CN2 are integrated to form a common communication channel or the sensor nodes 2 and 3 are connected to the second communication channel CN2. In the latter case, the sensor nodes 2 and 3 are capable of communicating with the aggregation node 4 and the cloud node 5 directly without passing through the control node 1. The second communication channel CN2 and the third communication channel CN3 may be integrated to construct a common communication channel.

The input/output device 405 is a device for exchanging information between the operator and the aggregation node 4. The operator can input an instruction to the input/output device 405 or cause the input/output device 405 to display a screen, if necessary. Examples of the input/output device 405 include a display, a keyboard, a mouse, a touch panel, a printer, a speech synthesis device, a speech recognition device, or the like.

The other system cooperation function F41 communicates with the substation automation system SA1 and the power distribution automation system SA2 through the communication device 403 and the third communication channel CN3. Thus, the aggregation node 4 can know, for example, an existing power distribution system diagram, a remote monitoring status, a power failure state, an accident situation, or the like. The aggregation node 4 acquires the entire situation from other external systems SA1 and SA2, and transmits the information detected by the control node 1 and the sensor nodes 2 and 3 under its management, to the other external systems SA1 and SA2. Thus, information is shared in the entire power distribution system.

The communication control/management function F42 communicates with the control node 1, the sensor nodes 2 and 3, the cloud node 5, and other aggregation nodes 4 using the communication device 403.

Based on the information acquired from each of the nodes 1, 2, 3, and 5 (and other aggregation nodes 4) and the information acquired from other systems SA1 and SA2 by other system cooperation functions, a system recognizing function F43 recognizes the state of the power distribution system. An input/output function F44 exchanges information with the operator using the input/output device 403.

In the present embodiment, a case is described where the control node 1, the sensor nodes 2 and 3, the aggregation node 4, and the cloud node 5 are configured as separate devices, respectively. However, the present invention is not limited to this, it may be configured such that a plurality of devices is integrated into one device, or one device is divided into a plurality of devices.

For example, any one of the plurality of control nodes 1 distributed in the power distribution system may have the function of the aggregation node 4 and know the entire power distribution system. It may be configured such that one or a plurality of control nodes 1 may have a function of the cloud node 5 so as to accept a data process from the sensor node 3. Each of the nodes 1, 2, 3, 4, and 5 may be further divided into a plurality of devices for cooperation. For example, the storage device may be configured as a separate storage device from each node. The storage device of each of the nodes 1, 2, 3, 4, and 5 may be configured as logical volumes to be provided from one storage device.

Furthermore, each function of each of the nodes 1, 2, 3, 4, and 5 may be partially replaced or integrated.

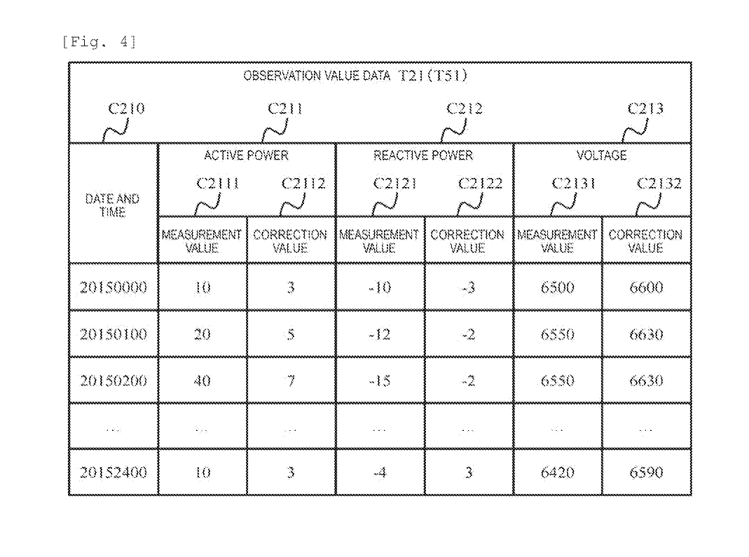

FIG. 4 shows an example of a table of the observation value database T21. Since the observation value database T21 of the sensor node 2 and the observation value database T51 of the cloud node 5 have the same configuration, the observation value database T21 will be mainly described.

The observation value database T21 includes, for example, date and time C210 representing the observation date and time, active power C211, reactive power C212, and voltage C213. These values C210 to C213 are generated by the observation/value processing function F21.

The active power C211 has a measurement value C2111 and a correction value C2112. The reactive power C212 also has a measurement value C2121 and a correction value C2122. The voltage C213 also has a measurement value C2131 and a correction value C2132. As the correction value, for example, a measurement error of the monitoring device 8 or the observation device 305 which is a measurement device, and processing calculation values necessary for measurement such as normalization are stored.

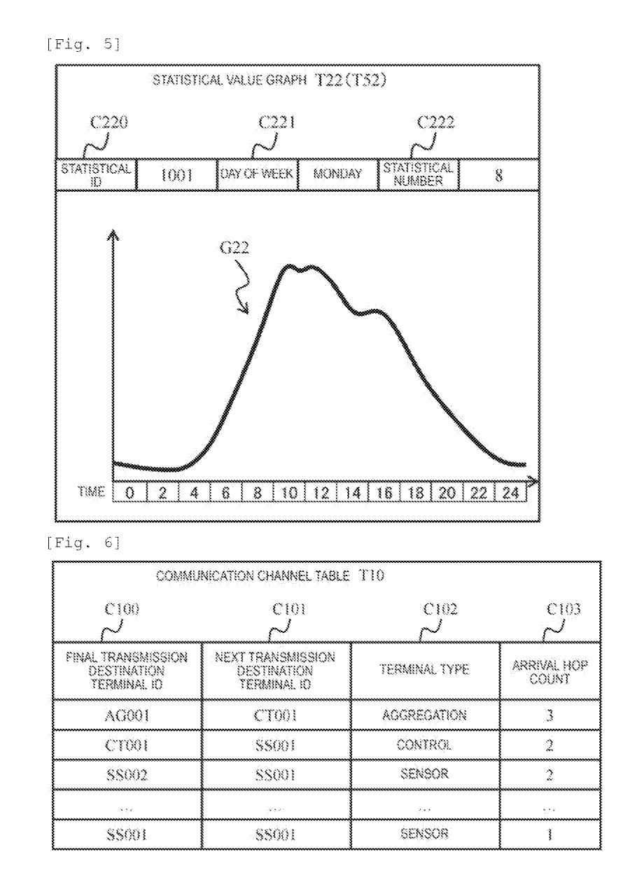

FIG. 5 shows an example of a table of statistical values recorded in the statistical value database T22. Since the statistical value database T22 of the sensor node 2 is the same as the statistical value database T52 of the cloud node 5, the statistical value database T22 will be mainly described.

The statistical value database T22 is configured to include, for example, a statistical ID C220 representing the type of the statistical value, a day of the week C221, and a statistical number C222 representing the number of observation values used to generate statistics. A graph G22 shows an example in which how the observation value changes with time is calculated by averaging the values of the past eight points. The horizontal axis of the graph G22 shows time and the vertical axis shows observation values.

The statistical value database T22 (T52) can be generated by the system state estimating functions F23 and F53. By using the statistical value database T22 (T52), future system change can be predicted from past observation values, and in a case where the observation values change from a certain period, it can be estimated whether a new distributed power supply 9 is connected to the power distribution system. FIG. 5 shows a statistical process for one observation value, but actually, the statistical process is performed for each observation value such as active power, reactive power, and a voltage. The statistical process may be performed by observing a frequency change.

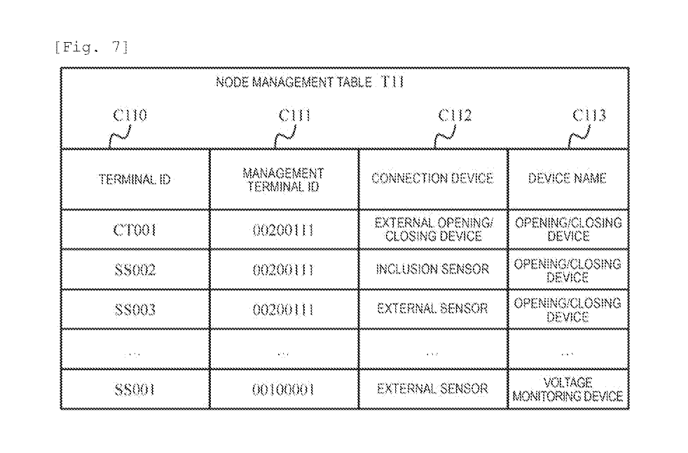

FIG. 6 shows an example of the communication channel table T10 managed by the communication control/management functions F12, F22, F32, F42, and F52.

The communication channel table T10 includes, for example, a final transmission destination terminal ID C100, a terminal ID C101 of the next transmission destination, a terminal type C102, and an arrival hop count C103.

In the present embodiment, the terminal type C102 is added in addition to the configuration of the communication channel table used in the Internet or the like. In the terminal type C102 shown in FIG. 6, “aggregation” is set for the aggregation node 4, “control” is set for the control node 1, and “sensor” is set for the sensor nodes 2 and 3. The arrival hop count C103 is the number of hops required from the self node to the final destination node having the final transmission destination terminal ID.

In the present embodiment, the first communication channel CN1 uses wireless communication, and the sensor nodes 2(1), 3(1), 2(2), and 3(2) and the control nodes 1(1) and 1(2) construct a multi-hop network by wireless communication. In addition, a method of constructing the wireless multi-hop network is known to those skilled in the art, and omitting the description does not affect the production or use of the autonomous monitoring system according to the present embodiment. Therefore, the method of constructing the wireless multi-hop network will be omitted.

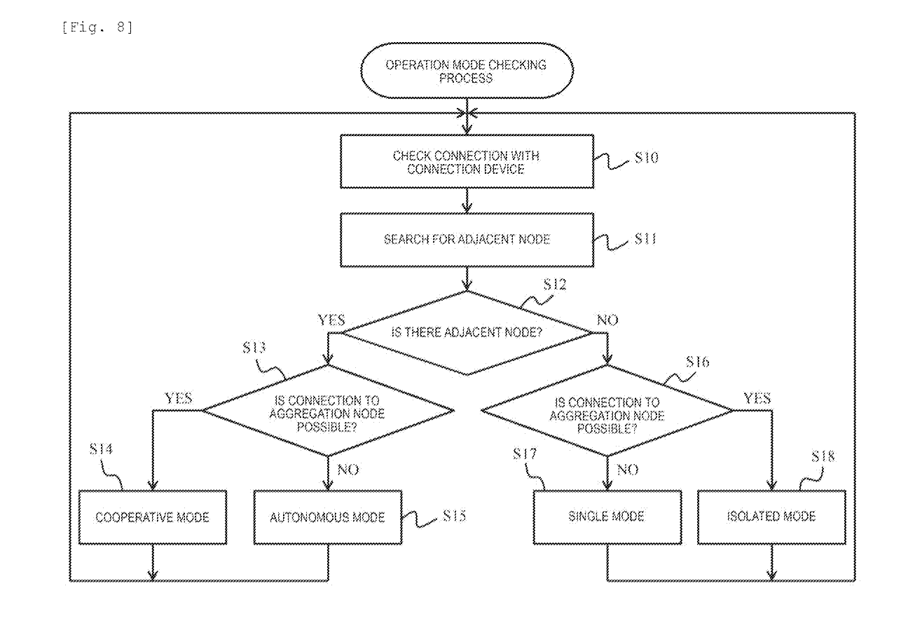

FIG. 7 shows an example of the node management table T11 managed by the communication control/management functions F12, F22, F32, F42, and F52. The node management table T11 manages the correspondence relationship among the control node 1, the sensor nodes 2 and 3, the aggregation node 4, the cloud node 5, and the predetermined control device provided on the power distribution system.

The node management table T11 includes, for example, a terminal ID C110, a management terminal ID C111, a connection device C112, and a device name C113.

The terminal ID C110 is information for identifying each node. The management terminal ID C111 is a representative identifier in a case where a plurality of nodes is integrated or grouped. For example, the control node 1(1) and the sensor nodes 2(1) and 3(1) shown in FIG. 1 constitute one autonomous monitoring group, and the control node 1(2) and the sensor nodes 2(2) and 3(2) constitute the other autonomous monitoring group. The management terminal ID C111 is an identifier (group identifier) for identifying a group.

Incidentally, for example, the control node 1 and the sensor nodes 2 and 3 may be provided in one terminal device. The autonomous monitoring type group may include any one of the control node 1, the sensor node 2, and the sensor node 3, and it is not necessary to include all three types of nodes 1, 2, and 3.

The connection device C112 is information indicating a connection destination device to which each node is connected. Examples of the connection device C112 include a control device (for example, the opening/closing device 7) existing externally, an inclusion sensor (for example, the observation device 305) provided in the sensor node 3, and an external sensor (for example, the monitoring device 8) provided outside the sensor node 2. The device name C113 is the name of the device targeted by the group to which each node belongs. In the above example, one autonomous monitoring group (1(1), 2(1), and 3(1)) targets one opening/closing device 7(1), the other autonomous monitoring group (1(2), 2(2), and 3(2)) targets the other opening/closing device 7(2). Other examples of the target device include a voltage monitoring device or the like.

By using the node management table T11 shown in FIG. 7, for example, the remote control target device such as the opening/closing device 7 provided with the monitoring device 8 can be identified and managed by the control node 1 and the sensor nodes 2 and 3.

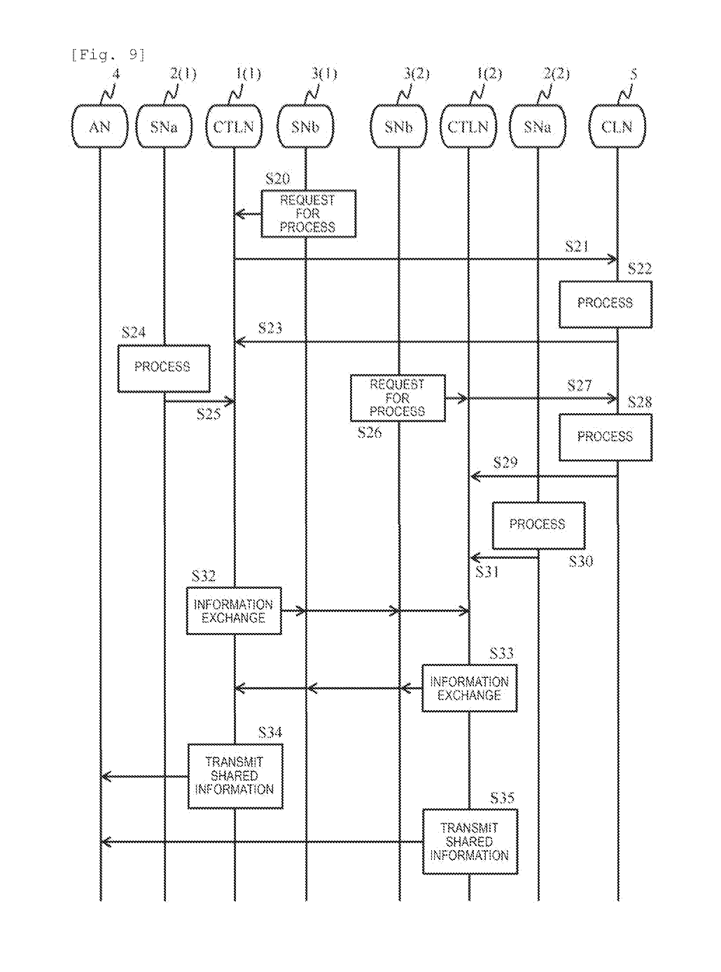

FIG. 8 is a flowchart showing a process of checking an operation mode of each of the nodes 1, 2, and 3 constituting the autonomous monitoring group. The control node 1 and the sensor nodes 2 and 3 execute this process at the time of startup, periodically, or at a predetermined trigger. As a result, each of the nodes 1, 2, and 3 checks the operation mode of the self node and makes a determination. First, each mode will be described.

In the first communication channel CN1, the control node 1 and each of the sensor nodes 2 and 3 autonomously constitute a wireless communication channel, and change the operation mode depending on the situation of the wireless communication channel. In the present embodiment, a plurality of types (four types) of an autonomous mode, a cooperative mode, a single mode, an isolated mode are prepared in advance as operation modes.

As will be described later, the autonomous mode is selected in a case where there is an adjacent node (S12: YES) and cannot be connected to the aggregation node 4 (S13: NO). Here, the adjacent node is a node capable of communicating within a predetermined hop count using the first communication channel CN1. The autonomous mode is a mode in which the control node 1 and the sensor nodes 2 and 3 autonomously perform monitoring and control, respectively. A node operating in the autonomous mode exchanges information with nodes of other groups and shares it, and makes logic determination and controls the target device (for example, the opening/closing device 7). For example, the node belonging to one group can make a determination about the operation of the target device (for example, whether to open or close the opening/closing device 7, or the like), from the information owned by the self node and the information received from the node belonging to another group. That is, in the autonomous mode, autonomous monitoring and control can be performed for each autonomous monitoring group.

As will be described later, the cooperative mode is selected in a case where there is an adjacent node (S12: YES) and connection to the aggregation node 4 is possible (S13: YES). The cooperative mode is a mode in which the node operates in the autonomous mode and can also operate based on a command from the aggregation node 4.

A node following the cooperative mode operates in the autonomous mode, in a case of not receiving a command from the aggregation node 4. However, in a case of receiving the command from the aggregation node 4, the node according to the cooperative node operates according to the command from the aggregation node 4.

Since the aggregation node 4 cooperates with external systems such as another aggregation node 4, the substation automation system SA1, and the power distribution automation system SA2, it is possible to know the entire power distribution system and issue appropriate commands. That is, for example, even if it is an optimal operation for a certain autonomous monitoring group and another adjacent autonomous monitoring group, the operation is merely to realize partial optimization, and it is not always optimal for the entire power distribution system. Therefore, it is possible to optimize the control of the entire power distribution system by occasionally giving a command from the aggregation node 4 to the node following the autonomous mode for partial optimization.

As will be described later, the single mode is selected, in a case where there is no adjacent node (S12: NO) and cannot be connected to the aggregation node 4 (S16: NO). The sensor nodes 2 and 3 following the single mode perform only observation and monitoring. The control node 1 following the single mode performs only monitoring, and does not control the target device.

As will be described later, the isolated mode is selected in a case where there is no adjacent node (S12: NO) and connection to the aggregation node 4 is possible (S16: YES). For example, since only one isolated control node 1 is connected to the aggregation node 4 through the second communication channel CN2, it operates according to an isolated node. Basically, a node according to the isolated node performs monitoring in the same way as in the single mode, but if it receives a command from the aggregation node 4, it operates according to the command.

A description will be made with reference to the flowchart of FIG. 6. This process is executed by each of the nodes 1, 2, and 3, respectively. The target node checks the connection with the connection device (S10). The target node searches for an adjacent node, and updates the communication management table T10 illustrated in FIG. 6 (S11).

From the search result of step S11, the target node determines whether there is an adjacent node (S12). When determining that there is the adjacent node (S12: YES), the target node exchanges and shares the information on the connection device, and updates the node management table T11 illustrated in FIG. 7.

In a case of detecting the presence of the adjacent node (S12: YES), the target node determines whether connection to the aggregation node 4 is possible (S13). In a case where the target node is the control node 1, the target node is directly connected to the aggregation node 4 through the second communication channel CN2. In a case where the target node is one of the sensor nodes 2 and 3 and the adjacent node is the control node 1, the target node is connected to the adjacent node (control node 1) through the first communication channel CN1, and can be connected to the aggregation node 4 through the adjacent node and the second communication channel CN2.

In a case where there is an adjacent node (S12: YES) and it is determined that connection to the aggregation node 4 is possible (S13: YES), the target node selects the cooperative mode as the operation mode (S14). On the other hand, in a case where there is an adjacent node (S12: YES) and it is determined that the target node cannot be connected to the aggregation node 4 (S13: NO), the target node selects the autonomous mode as the operation mode.

On the other hand, in a case of determining that there is no adjacent node (S12: NO), the target node determines whether connection to the aggregation node 4 is possible (S16). In a case where there is no adjacent node (S12: NO) and it is determined that connection to the aggregation node 4 is not possible (S16: NO), the target node selects the single mode as the operation mode. On the other hand, in a case where there is no adjacent node (S12: NO) and it is determined that connection to the aggregation node 4 is possible (S16: YES), the target node selects the isolated mode as the operation mode (S18).

In the present embodiment, the aggregation node 4 and cloud node 5 are connected to the control node 1 through the second communication channel CN2, but it may be configured such that the aggregation node 4 and the cloud node 5 are also connected to the first communication channel CN1.

The first communication channel CN1 of the present embodiment is constructed using short-range wireless communication and is different from the second communication channel CN2 capable of communicating wirelessly at medium or long distance such as cellular phone communication network. The first communication channel CN1 is short in its communication distance and is also easily affected by obstacles such as trucks parked and stopped and buildings. Therefore, the communication network constructed by the first communication channel CN varies depending on the situation of the installation place of each node, the channel that was connected until yesterday may be disconnected today, or the channel that was not connected until yesterday may be connected today. In order to cope with the feature of the first communication channel CN1, in the present embodiment, as shown in FIG. 8, the operation mode of each node is determined according to the situation of the first communication channel CN1. Thus, in the present embodiment, each node can select an appropriate operation mode depending on the situation of the first communication channel CN1, and can operate autonomously.

In the present embodiment, each of the nodes 1, 2, and 3 adopts the first communication channel CN1 capable of autonomously constructing a communication network using short-range wireless communication, so that each of the nodes 1, 2, and 3 can be provided in an arbitrary place of the power distribution system. In the present embodiment, nodes 1, 2, and 3 communicates with each other, so that the first communication channel CN1 can be autonomously constructed. In the present embodiment, while taking advantage of the feature of the first communication channel CN1 capable of autonomously constructing the communication network according to the situation of the site of the power distribution system (presence or absence of an obstacle, or the like), each of the nodes 1, 2, and 3 participating in the first communication channel CN1 voluntarily selects the operation mode suitable for the self node. Thus, in the present embodiment, an autonomous monitoring system capable of flexibly and promptly dealing with the configuration change of the power distribution system is realized. Therefore, if the aggregation node 4 and the cloud node 5 also participate in the first communication channel CN1, each node may determine only the operation mode of the self node periodically or irregularly according to the process as shown in FIG. 8.

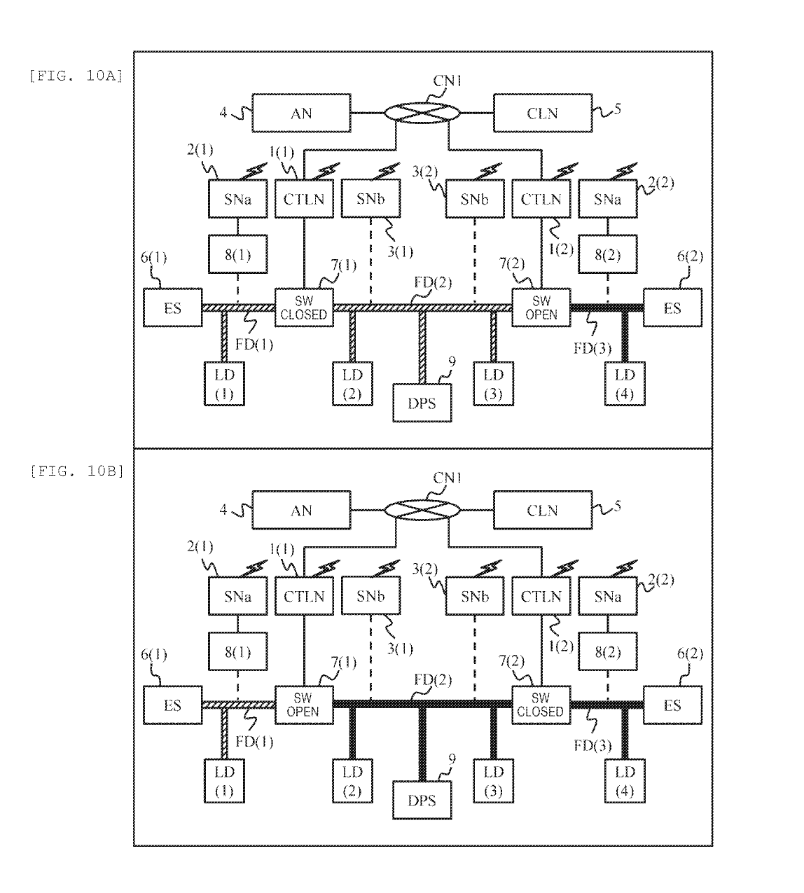

FIG. 9 shows the processing sequence of each of the nodes 1, 2, 3, 4, and 5. In FIG. 9, it is assumed that the control node 1 and the sensor nodes 2 and 3 operate in either autonomous mode or cooperative mode. In FIG. 9, the aggregation node 4 is indicated as “AN 4”, the sensor node 2 as “SNa 2”, the control node 1 as “CTLN 1”, and the sensor node 3 as “SNb 3”. First, the operation of one autonomous monitoring group will be described.

When the generation timing of the statistical value database T52 arrives, the sensor node 3(1) requests the cloud node 5 to perform a statistical process (S20). The statistical process request is sent from the sensor node 3(1) to the control node 1(1) through the first communication channel CN1, and is sent from the control node 1(1) to the cloud node 5 through the second communication channel CN2 (S21).

In the present embodiment, the manufacturing cost of the sensor node 3 is reduced so that more sensor nodes 3 can be added to the power distribution system. In order to reduce the manufacturing cost, the sensor node 3 has a lower performance than the sensor node 2. For example, the sensor node 3 does not have a function of processing observation values. Furthermore, since the sensor node 3 does not store observation values for a long time, the capacity of the storage device 304 may be small. Since the manufacturing cost is reduced, the sensor node 3 causes the cloud node 5 to substitute the observation value storage and statistical processing.

In this way, the sensor node 3(1) transmits the observation value detected by the observation device 305 to the cloud node 5 through the control node 1. Examples of the transmission method of the observation value include sequential transmission that performs transmission each time an observation value is acquired, and batch transmission that collectively transmits a predetermined amount of observation values. Which of the sequential transmission and the batch transmission is to be selected may be determined based on the congestion degree of the first communication channel CN1, the situation of communication delay, or the like.

Upon receipt of the observation value from the sensor node 3(1), the cloud node 5 stores the observation value in the observation value database T51, processes the observation value, and stores the processed value in the statistical value database T52. The cloud node 5 transmits the processing result of the observation value (the result of the statistical process) to the control node 1(1) through the second communication channel CN2 (S23).

On the other hand, the sensor node 2(1) has a function F21 of processing observation values, and includes an observation value database T21 storing observation values for a long term. Therefore, the sensor node 2(1) executes accumulation and processing of observation values (statistical process of observation values) at the self node 2(1), and updates the observation value database T21 and the statistical value database T22 (S24). The sensor node 2(1) transmits the processing result of the observation value (the result of the statistical process) to the control node 1(1) through the first communication channel CN1 (S25).

The other autonomous monitoring group also operates like one autonomous monitoring group. The sensor node 3(2) requests the cloud node 5 to perform a statistical process, through the control node 1(2) (S26). The control node 1(2) requests the cloud node 5 to substitute the statistical process, through the second communication channel CN2 (S27).

The cloud node 5 stores the observation value from the sensor node 3(2) in the observation value database T51, processes the observation value, and stores the processed value in the statistic value database T52 (S28). The cloud node 5 transmits the result of the statistical process to the control node 1(2) through the second communication channel CN2 (S29).

The sensor node 2(2) also stores the observation value acquired from the monitoring device 8(2) in the observation value database T21, statistically processes the observation value, and stores it in the statistical value database T22 (S30). The sensor node 2(2) transmits the result of the statistical process to the control node 1(2) through the first communication channel CN1 (S31).

Next, adjacent autonomous monitoring groups exchange and share statistical information. The control node 1(1) of one group transmits statistical information of the sensor node 2(1) and statistical information of the sensor node 3(1) through the first communication channel CN1 to the control node 1(2) of the other group (S32). The control node 1(2) of the other group stores the statistical information received from the control node 1(1) of one group in the storage device 104.

Similarly, the control node 1(2) of the other group also transmits the statistical information of the sensor node 2(2) and the statistical information of the sensor node 3(2) through the first communication channel CN1 to the control node 1(1) of one group (S33). The control node 1(1) of one group stores the statistical information received from the control node 1(2) of the other group in the storage device 104.

When information sharing is completed between the control node 1(1) and the control node 1(2) of the adjacent groups, each of the control nodes 1(1) and 1(2) transmits the held or acquired information to the aggregation node 4 through the second communication channel CN2 (S34 and S35). Thus, the aggregation node 4 managing these autonomous monitoring groups knows the situation of the power distribution system, based on the statistical processing data in each group.

In a case where information is transmitted from the control nodes 1(1) and 1(2) to the aggregation node 4, it is possible to control communication, according to, for example, the congestion degree of the second communication channel CN2, the available communication capacity, the processing load of the aggregation node 4, the processing loads of the control nodes 1(1) and 1(2), or the like. For example, only the difference from the previously transmitted information may be transmitted from the control nodes 1(1) and 1(2) to the aggregation node 4.

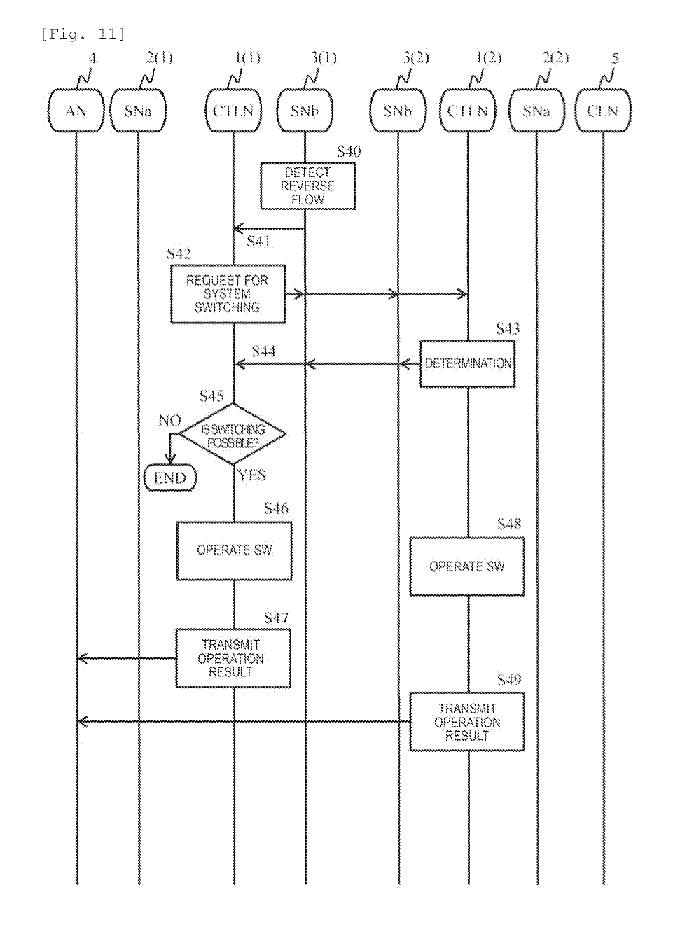

With reference to FIG. 10, how the control nodes of adjacent groups cooperate to change the configuration of the power distribution system will be described. FIG. 10(a) shows the state before switching the power distribution system and FIG. 10(b) shows the state after switching the power distribution system. In FIG. 10, the opening/closing device is abbreviated as “SW” and the substation is abbreviated as “ES”.

In the state before switching the power distribution system in FIG. 10(a), one opening/closing device 7(1) is closed. Thus, the power distribution line FD(1) and the power distribution line FD(2) are electrically connected through the opening/closing device 7(1). On the other hand, since the other opening/closing device 7(2) is open, the power distribution line FD(2) and the power distribution line FD(3) are blocked at the opening/closing device 7(2).

Therefore, the power supplied from the substation 6(1) flows to the opening/closing device 7(2) through the power distribution lines FD(1) and FD(2). The power supplied from the substation 6(2) flows to the opening/closing device 7(2) through the power distribution line FD(3).

FIG. 10(b) shows a case where the opening and closing states of the opening/closing devices 7(1) and 7(2) are switched. The opening/closing device 7(1) is open and the opening/closing device 7(2) is closed. As a result, the power supplied from the substation 6(1) flows to the opening/closing device 7(1) through the power distribution line FD(1). The power supplied from the substation 6(2) flows to the opening/closing device 7(1) through the power distribution line FD(3).

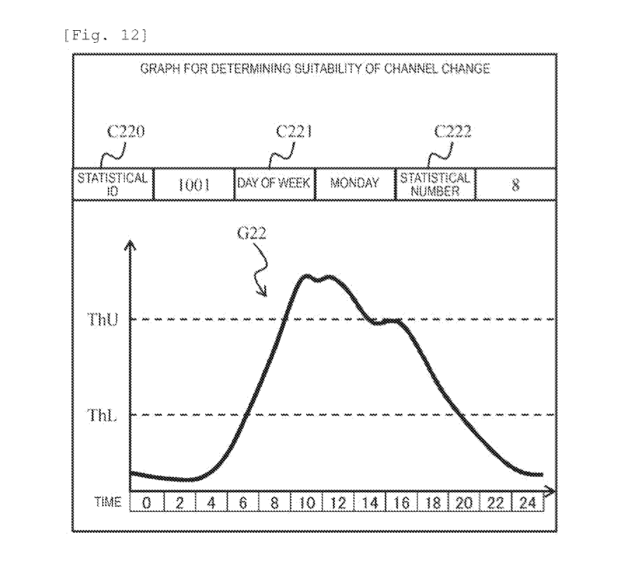

FIG. 11 is a sequence diagram showing the process in which autonomous monitoring groups cooperate with each other to autonomously change the system. This process is executed on the premise of the statistical information sharing shown in FIG. 9.

It is assumed that the initial configuration of the power distribution system is the configuration shown in FIG. 10(a). In the configuration of the power distribution system shown in FIG. 10(a), it is assumed that the sensor node 3(1) of one group detects a reverse flow by the observation device 305 (S40). The sensor node 3(1) notifies the control node 1(1) that arranges one group through the first communication channel CN1 that the reverse flow is detected (S41).

Upon receipt of the reverse flow detection notification from the sensor node 3(1), the control node 1(1) estimates that the occurrence of the reverse flow is caused by the output from the distributed power supply 9. The control node 1(1) requests the control node 1(2) that arranges the other group to perform system switching in order to resolve the reverse flow by changing the configuration of the power distribution system (S42).

Upon receipt of the request for system change from one control node 1(1), the other control node 1(2) determines whether the requested system switching is appropriate (S43). A method of determining whether it is appropriate or not will be described later with reference to FIG. 12.

The other control node 1(2) transmits the determination result in step S43 to one control node 1(1) through the first communication channel CN1 (S44). One control node 1(1) determines whether or not the power distribution system switching is possible on the self node side (S45). If one control node 1(1) determines that it is not possible to switch the power distribution system (S45: NO), this process is terminated.

When it is determined that the power distribution system switching is possible (S45: YES), one control node 1(1) operates the opening/closing device 7(1) to switch the opening/closing device 7(1) from the open state to the closed state (S46). One control node 1(1) transmits the operation result in step S46 to the aggregation node 4 (S47).

The other control node 1(2) also operates the opening/closing device 7(2) according to the determination result of step S43 and switches the opening/closing device 7(2) from the open state to the closed state (S48).

With the above process, when a reverse flow is detected, the power distribution system changes from the configuration shown in FIG. 10(a) to the configuration shown in FIG. 10 (b).

FIG. 12 is a statistical value graph for use in determining whether or not to perform system switching. FIG. 12 is obtained by adding an upper limit ThU and a lower limit ThL to the statistical value graph G22 shown in FIG. 5.

For example, the control node 1(2) acquires the power fluctuation in the power distribution line FD(3), and further acquires the upper limit and the lower limit of the power fluctuation. This is because constant quality is required for power supply. The power transmission and distribution business operator needs to supply power within a predetermined range defined by a predetermined upper limit and a predetermined lower limit.

Based on the information received from the control node 1(1), the control node 1(2) acquires the power fluctuation in the power distribution line FD(2), and determines whether the power fluctuation falls within a predetermined range. In a case of determining that the power fluctuation falls within a predetermined range, the control node 1(2) can respond to the system switching (system configuration change) described in step S42. On the contrary, in a case of determining that the power fluctuation does not fall within a predetermined range, the control node 1(2) does not respond to the system switching.

However, even in a case where the power fluctuation is within the predetermined range, in a case where it can be determined that the information acquired from the control node 1(1) is highly likely to differ from the actual state, the control node 1(2) may refuse the request for system switching from the control node 1(1).

For example, in photovoltaic power generation, in some cases, it can be estimated that the power generation amount is greatly reduced due to weather deterioration. In wind power generation, it can be estimated that the power generation amount is zero in a case where the wind turbine is stopped due to weather deterioration. Alternatively, in wind power generation, the wind condition changes depending on a climate change, and in some cases, it can be estimated that the power generation amount fluctuates largely. Furthermore, in a case where there are plans to charge a large number of electric vehicles all at once, it can be estimated that the load increases rapidly at the scheduled charging time. Furthermore, it can be estimated that the power fluctuation of the power distribution system changes rapidly even in a case where discharge from a large number of plug-in hybrid vehicles to the power distribution system is predicted. In this way, if there is a ground for doubting the reliability of the information on the state of the power distribution system recognized by the control node 1(1), the control node 1(2) may decline the request for system switching from the control node 1(1).

According to the present embodiment configured as described above, only by adding the control node 1, the sensor nodes 2 and 3, or the like to the existing power distribution system (system control system), it is possible to strengthen the monitoring function and improve the function of the existing power distribution system.

In the autonomous monitoring system of the present embodiment, it is possible to easily add an autonomous monitoring function and an autonomous control function to places where the existing power distribution system cannot perform sufficient monitoring. Thus, in the present embodiment, even in a case where a large number of distributed power supplies 9 are connected to the power distribution system, it is possible to promptly detect the necessity of system change and implement system change at an early stage. As a result, in the present embodiment, it is possible to reduce the power loss in power supply, realize a rational and stable system operation, and improve the reliability of the power distribution system.

It is not preferable that frequent system change (system switching) occurs. Therefore, it may be configured such that the history of the system change is stored in the storage device 104 of the control node 1 and a new system change is not permitted until a predetermined time elapses from the previous system change time in order to suppress frequent system change. Alternatively, the frequency of system change can be reduced by setting a period for calculating the statistical value from observation values longer or by setting the threshold for determination to a moderate value. Thus, device lifetime of the opening/closing device 7 or the like is also improved.

Although only one aggregation node 4 is shown in the present embodiment, the present invention is not limited to this, and a hierarchical structure may be formed from a plurality of aggregation nodes 4. An example of the hierarchical aggregation node 4 will be described later.

### Embodiment 2

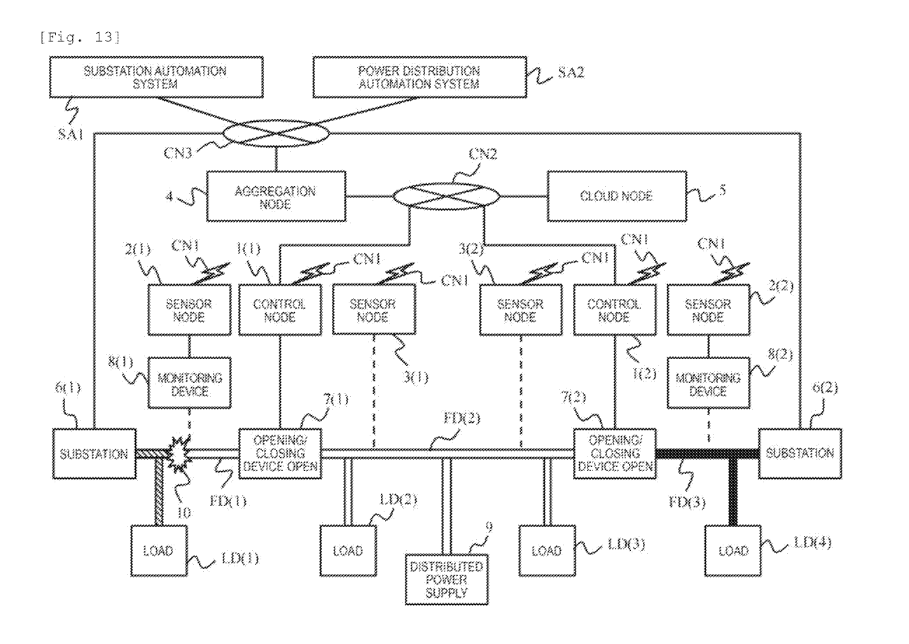

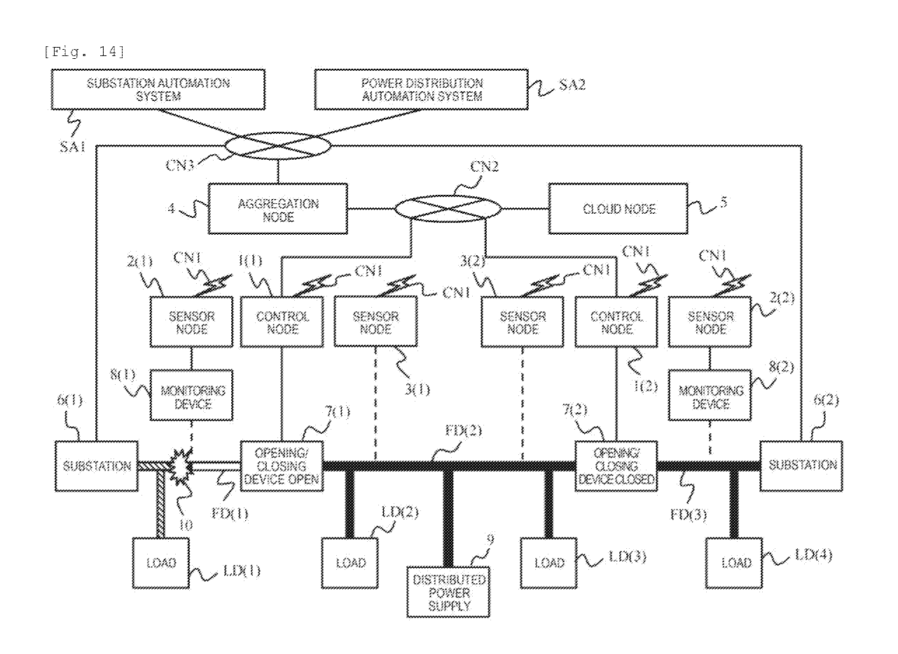

A second embodiment will be described with reference to FIG. 13 to FIG. 15. Since the following embodiments including this embodiment correspond to modification examples of the first embodiment, the difference from the first embodiment will be mainly described. In the present embodiment, a case where a power failure is restored will be described as an example.

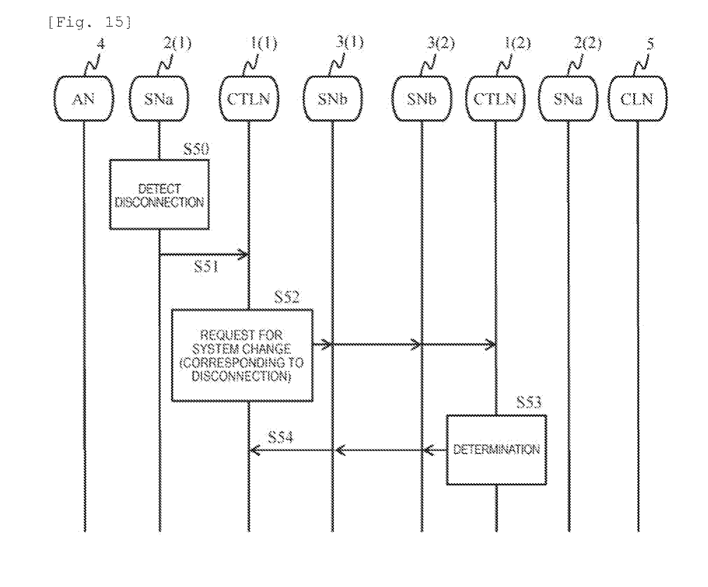

FIG. 13 and FIG. 14 show the entire power distribution system with an autonomous monitoring system. FIG. 13 shows the power distribution system when a power failure occurs, and FIG. 14 shows the power distribution system when it is restored from the power failure.

In the example shown in FIG. 13, disconnection 10 occurs between the power distribution line FD(1) and the opening/closing device 7(1). The opening/closing device 7(1) opens the circuit when the disconnection 10 is detected. As a result, since the substation 6(1) and the power distribution line FD(2) are blocked by the opening/closing device 7(1), the power from the substation 6(1) is not supplied to the power distribution line FD(2).

FIG. 14 shows a state in which the operation of the opening/closing device 7(2) is switched for the purpose of restoration from a power failure at an early stage. As a result of information exchange with the control node 1(1), the control node 1(2) determines that the opening/closing device 7(2) should be closed when detecting the occurrence of power failure 10. When the opening/closing device 7(2) is closed by the operation of the control node 1(2), the substation 6(2) and the power distribution line FD(2) are connected through the opening/closing device 7(2). As a result, the power supplied from the substation 6(2) flows from the power distribution line FD(3) to the power distribution line FD(2) through the opening/closing device 7(2). Thus, power from the substation 6(2) is supplied to the loads LD(2) and LD(3) connected to the power distribution line FD(2), and the power failure in the power distribution line FD(2) is resolved.

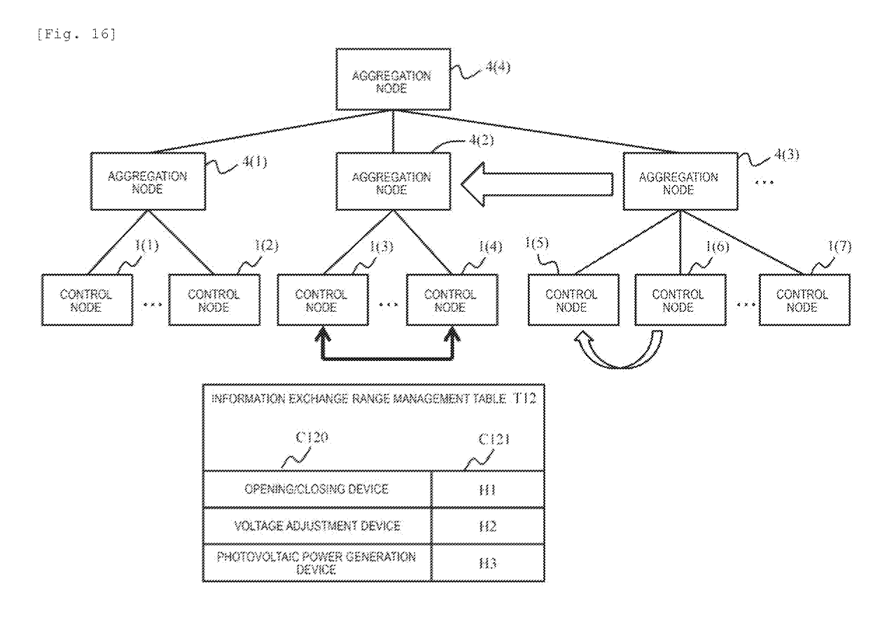

FIG. 15 is a sequence diagram in a case where a power failure is restored. This process is also based on the exchange of information between the control nodes 1 shown in FIG. 9.

The sensor node 2(1) detects the disconnection 10 by the monitoring device 8(1) (S50). The sensor node 2(1) notifies control node 1(1) of the disconnection detection information indicating that the disconnection has been detected, through the first communication channel CN1 (S51).

Upon receipt of the disconnection detection information from the sensor node 2(1), the control node 1(1) opens the opening/closing device 7(1) in order to separate the disconnection section from the power distribution system. Thus, the power distribution system is in the state shown in FIG. 13. Here, when the opening/closing device 7(1) is opened, the control node 1(1) recognizes that power failure occurs in the section of the power distribution line FD(2). Therefore, the control node 1(1) requests the control node 1(2) to change the system for restoration from the power failure of the power distribution line FD(2) at an early stage (S52).

Upon receipt of the request for system change from the control node 1(1), the control node 1(2) determines the suitability of system change (S53). An example of the determination method has been described in the first embodiment, so the description thereof is omitted here. The control node 1(2) transmits the determination result to the control node 1(1) (S54). Although not shown in the sequence diagram, the control node 1(2) closes opening/closing device 7(2) and supplies power from the substation 6(2) to the power distribution line FD(2) to resolve the power failure of the power distribution line FD(2). The state where the power failure is restored is shown in FIG. 14.

In the present embodiment configured as described above, the same operation and effect as those of the first embodiment can be obtained. Furthermore, in the present embodiment, a power failure can be restored at an early stage, and the reliability of the power distribution system can be further improved.

In the present embodiment, for restoration from a power failure in the power distribution line FD(2), the connection between the substation 6(1) and the power distribution line FD(2) is blocked, and the substation 6(2) and the power distribution line FD(2) are connected instead thereof, but instead of this, the distributed power supply 9 may be used. For example, the opening/closing devices 7(1) and 7(2) located at both ends of the power distribution line FD(2) are respectively closed to isolate the power distribution line FD(2) from the power distribution system, and power from the distributed power supply 9 is supplied to the isolated power distribution line FD(2). In a case where the power generation amount of the distributed power supply 9 is sufficiently large, and/or the loads LD(2) and LD(3) can be suppressed, a single supply system by the distributed power supply 9 can be realized. This enables the section of the power distribution line FD(2) to be restored from power failure.

For example, in a case where the distributed power supply 9 is a large-scale photovoltaic power generator, and in a case where disconnection 10 occurs during daytime in fine weather, a large amount of power generation from the distributed power supply 9 is expected. In a case where there is a possibility that a reverse flow may occur by closing the opening/closing device 7(2), the opening/closing device 7(2) may be closed by selecting the time zone during which the output of the photovoltaic power weakens. This enables the power failure occurring in the section of the power distribution line FD(2) to be restored, and makes it possible to operate the system with the minimum power loss of the power distribution system.

### Embodiment 3

A third embodiment will be described with reference to FIG. 16. In the present embodiment, a hierarchical structure is formed from a plurality of aggregation nodes 4, and an information exchange range between control nodes 1 is controlled according to a target device type.

FIG. 16 shows the outline of the connection state of the aggregation node 4 and the control node 1. The descriptions of the sensor nodes 2 and 3 and the cloud node 5 are omitted.

In the present embodiment, for example, lower aggregation nodes 4(1) to 4(3) are provided at the branch points of the power distribution system, and a higher aggregation node 4(4) is provided within the substation 6. The lower aggregation nodes 4(1) to 4(3) are responsible for recognizing the power distribution system at the point where the power distribution line FD branches off. The higher aggregation node 4(4) is responsible for recognizing all power distribution systems extending from the substation 6.

In a case where a processing load increases or a failure occurs in any of the aggregation nodes among the lower aggregation nodes 4(1) to 4(3), it is also possible to request other normal lower aggregation nodes to perform a process. In FIG. 16, the lower aggregation node 4(3) requests the different lower aggregation node 4(2) to substitute the process of the lower aggregation node 4(3).

Similarly, in a case where a processing load increases or a failure occurs, the control node 1 can also request another adjacent control node 1 to perform a process. FIG. 16 shows how processing can be inherited between the control node 1(3) and the control node 1(4). In other words, it is possible to set a failover group between adjacent control nodes 1 among control nodes 1 distributed and disposed in the power distribution system.

As described in the first embodiment, the control node 1 exchanges information with another adjacent control node 1 in order to improve the reliability of the power distribution system or the like. Here, since the first communication channel CN1 is configured as a short range wireless communication network (for example, a wireless multi-hop network), control nodes are capable of communicating with each other within a hop possible range. However, there is no merit even if control nodes, which are less related to the monitoring and control of the power distribution system, exchange information, and the capacity of the storage device 104 is consumed wastefully.

Therefore, in the present embodiment, an information exchange range management table T12 defining the information exchange range between control nodes is prepared. The management table T12 includes, for example, a target device type C120 and an upper limit hop count C121. The target device type C120 is the type of a device to be monitored or controlled by the control node 1, and includes, for example, “an opening/closing device”, “a voltage adjustment device”, “a photovoltaic power generation device”, or the like. The upper limit hop count C121 defines the upper limit of a communication distance from another control node 1 with which information is exchanged.

For example, the upper limit hop count H1 in a case where the target device is “opening/closing device” is 2, the upper limit hop count H2 in a case where the target device is the “voltage adjustment device” is 3, and the upper limit hop count H3 in a case where the target device is the “photovoltaic power generator” is 3. Here, in a case where the target device is a device involved in the system change, the management table T12 can be set such that the information exchange range becomes smaller than that of the device not involved in the system change (H 1>H 2, H 1>H3). That is because it is useless even if the control node involved in the system change exchanges information with another control node not directly involved in the system change. On the other hand, the control node involved in the system change can be used to determine whether the system should be changed by referring to observation values and statistical values possessed by the control node not directly involved in the system change. Therefore, to widely collect observation values and statistical values, the information exchange range is widened.

In the present embodiment configured as described above, the same operation and effect as those of the first embodiment can be obtained. In the present embodiment, since the aggregation node 4 is hierarchized, the power distribution system can be appropriately recognized and managed for each section. Furthermore, in the present embodiment, since the information exchange range between the control nodes 1 is controlled according to the target device type, wasteful information exchange can be reduced.

In addition, the present invention is not limited to the above-described embodiments. Those skilled in the art can make various additions and modifications within the scope of the present invention.

### REFERENCE SIGNS LIST

1 CONTROL NODE
2 SENSOR NODE
3 SENSOR NODE
4 AGGREGATION NODE
5 CLOUD NODE
6 SUBSTATION
7 OPENING/CLOSING DEVICE
8 MONITORING DEVICE
9 DISTRIBUTED POWER SUPPLY
FD POWER DISTRIBUTION LINE

1. A monitoring system which autonomously monitors the state of a power distribution system, comprising;
a first device corresponding to a predetermined control device provided in the power distribution system;
a second device that measures the state of the power distribution system on an upstream side of the predetermined control device; and
a third device that measures the state of the power distribution system on a downstream side of the predetermined control device,
wherein the first device, the second device, and the third device are connected so as to be bi-directionally communicable with each other over a first communication channel, and
wherein the first device collects a measurement result of the second device and a measurement result of the third device to monitor the power distribution system.

2. The autonomous monitoring system for a power distribution system according to claim 1,
wherein the first device controls the operation of the predetermined control device, based on the measurement result of the second device and the measurement result of the third device.

3. The autonomous monitoring system for a power distribution system according to claim 2,
wherein a plurality of the predetermined control devices is provided in the power distribution system, and
wherein the first device, the second device, and the third device are provided for each of the predetermined control devices to form a group.

4. The autonomous monitoring system for a power distribution system according to claim 3,
wherein the second device measures the state of the power distribution system through an external measuring device provided in the power distribution system, and
wherein the third device measures the state of the power distribution system through a built-in measuring device.

5. The autonomous monitoring system for a power distribution system according to claim 4,
wherein the second device estimates the state of the power distribution system, based on the measurement result of the state of the power distribution system, and transmits the estimation result to the first device as the measurement result of the second device, and
wherein the third device requests a system state estimation unit, which estimates the state of the power distribution system based on the measurement result of the state of the power distribution system, to perform an estimation process, and the system state estimation unit transmits the estimation result to the first device as the measurement result of the third device.

6. The autonomous monitoring system for a power distribution system according to claim 5,
wherein in a case where the power distribution system is in a predetermined state, the first device controls the operation of the predetermined control device in order to change the configuration of the power distribution system to a predetermined configuration corresponding to the predetermined state.

7. The autonomous monitoring system for a power distribution system according to claim 6,
wherein an overall management device that recognizes a power distribution system to be managed among the power distribution systems is provided,
wherein the overall management device is connected so as to be bi-directionally communicable with the first device for each of the predetermined control devices, through a second communication channel different from the first communication channel, and
wherein the second device and the third device are communicable with the overall management device through the first device by communicating with the first device through the first communication channel.

8. The autonomous monitoring system for a power distribution system according to claim 7,
wherein the first device exchanges information with other first devices existing within a predetermined range, and
wherein the predetermined range is set according to the type of the predetermined control device.

9. The autonomous monitoring system for a power distribution system according to claim 8,
wherein each of the first device, the second device, and the third device
determines whether there is a different device capable of communicating through the second communication channel,
determines whether the device itself is capable of communicating with the overall management device through the first communication channel, in a case where the different device capable of communicating is detected,
operates in a first mode at which the device cooperates with the different device, in a case where it is determined that the device itself is not capable of communicating with the overall management device,
operates in a second mode at which the device cooperates with the different device and follows a command from the overall management device, in a case where it is determined that the device itself is capable of communicating with the overall management device,
determines whether the device itself is capable of communicating with the overall management device through the first communication channel, in a case where the different device capable of communicating cannot be detected,
operates in a third mode at which the device measures the state of the power distribution system when the device itself is either the second device or the third device, and stops an autonomous operation when the device itself is the first device, in a case where it is determined that the device itself is not capable of communicating with the overall management device, and
operates in a fourth mode at which the device follows the command from the overall management device, in a case where it is determined that the device itself is capable of communicating with the overall management device.

10. The autonomous monitoring system for a power distribution system according to claim 6,
wherein the predetermined state is at least one of occurrence of a reverse flow from a distributed power supply or occurrence of power failure.

11. The autonomous monitoring system for a power distribution system according to claim 7,
wherein the overall management device is configured to have a hierarchical structure formed from a first overall management device provided corresponding to the branch point of the power distribution system, and a second overall management device located above the first overall management device and provided within a substation connected to the power distribution system.

12. A method of monitoring a state of a power distribution system in an autonomous distributed manner, using a plurality of devices disposed in the power distribution system,
the plurality of devices including a first device corresponding to a predetermined control device provided in the power distribution system, a second device that measures the state of the power distribution system on an upstream side of the predetermined control device, and a third device that measures the state of the power distribution system on a downstream side of the predetermined control device,
the first device, the second device, and the third device being connected so as to be bi-directionally communicable with each other over short-range wireless communication,
the method comprising:
collecting a measurement result of the second device and a measurement result of the third device, by the first device;
determining whether the power distribution system is in a predetermined state, by the first device, based on the state of the power distribution system estimated from the measurement result of the second device and the state of the power distribution system estimated from the measurement result of the third device; and
controlling the operation of the predetermined control device, by the first device, in order to change the configuration of the power distribution system to a predetermined configuration corresponding to the predetermined state, in a case where it is determined that the power distribution system is in the predetermined state.

13. A first device used in a monitoring system which autonomously monitors a state of a power distribution system, the first device comprising;
a storage unit that stores a computer program for realizing a predetermined function;
an arithmetic processing unit that realizes the predetermined function by executing the computer program stored in the storage unit; and
a communication unit that communicates with a predetermined control device provided in the power distribution system, a second device that measures the state of the power distribution system on an upstream side of the predetermined control device, and a third device that measures the state of the power distribution system on a downstream side of the predetermined control device,
wherein the communication unit receives a measurement result of the second device and a measurement result of the third device,
wherein the storage unit stores each of the received measurement results,
wherein the arithmetic processing unit
determines whether the power distribution system is in a predetermined state, based on the state of the power distribution system estimated from the measurement result of the second device and the state of the power distribution system estimated from the measurement result of the third device,
generates a control command to change a configuration of the power distribution system to a predetermined configuration corresponding to the predetermined state, in a case where it is determined that the power distribution system is in the predetermined state, and
controls the operation of the predetermined control device by transmitting the generated control command from the communication unit to the predetermined control device.
